(19) United States
(12) Patent Application Publication
(10) Pub. No.: US 2013/0162225 A1
(43) Pub. Date: Jun. 27, 2013

(54) MULTIPHASE CONVERTER COMPRISING MAGNETICALLY COUPLED PHASES

(71) Applicants: Nils Draese, Feuerbach (DE); Mirko Schinzel, Stuttgart (DE)

(72) Inventors: Nils Draese, Feuerbach (DE); Mirko Schinzel, Stuttgart (DE)

(73) Assignee: ROBERT BOSCH GMBH, Stuttgart (DE)

(21) Appl. No.: 13/819,775

(22) PCT Filed: Aug. 26, 2011
(86) PCT No.: PCT/EP2011/064766

§ 371 Date: Feb. 28, 2013

(30) Foreign Application Priority Data
Sep. 3, 2010 (DE) 10 2010 040 202.8

(51) Int. Cl. H02M 3/04; H01F 38/00; H03H 7/18

(52) U.S. Cl. CPC H02M 3/04; H03H 7/18; H01F 38/00
USPC 323/218; 323/355

(57) ABSTRACT

Disclosed is a multiphase converter comprising multiple phases (11 to 16), each of which can be triggered using switching means (21 to 26), at least one phase (11) being magnetically coupled to at least three other phases (12, 14, 16) by corresponding coupling means (31, 36, 37).

### BACKGROUND OF THE INVENTION

The invention is based on a multiphase converter of the generic type. A multiphase converter of the generic type is known from WO 2009/114873 A1, for example. The DC/DC converter described therein comprises a coil having a non-linear inductive reactance, a switching system and an output filter. In this case, adjacent phases are coupled to one another.

A converter for converting electrical energy is already known from EP 1145416 B1. The latter thus proposes that the inductor size can be reduced by the use of coupled inductances. In this case, the coupled inductors are intended to be dimensioned such that the load currents of the partial branches mutually compensate for one another and do not lead to magnetic loading of the inductors. Only the differential current between the individual partial branches then leads to a magnetic field.

It is an object of the present invention to specify a multiphase converter which is distinguished by simple producibility and further reduction of the structural space, in particular by virtue of a smaller volume of the coupling means, and simple controllability.

### SUMMARY OF THE INVENTION

The multiphase converter according to the invention has the advantage over the prior art that a disturbing mutual influencing of the phases is minimized by the magnetic coupling of one phase to at least three further phases. In this case, the phases to be coupled are chosen such that an optimum compensation can be achieved. This is effected, in particular, by means of a current profile in opposite directions. In this case, the aim is for the phases to be magnetically coupled so as to minimize the resulting magnetic field on account of the coupled phases. It is thereby possible to have recourse to a coupling means of small design, such as a ferrite core, for example, for coupling the magnetic fluxes. A corresponding coupling enabled the magnetic field to be greatly reduced, such that the corresponding coupling means, for example a ferrite core, can also be correspondingly reduced in terms of its mass. In the case of the proposed coupling, the phases can be driven in order. Relatively simple and thus easily controllable current profiles arise in this case. Particularly expediently, one phase—in the case of an arrangement comprising six phases—is coupled to the two respectively adjacent phases and also to a phase shifted by 180 degrees. An adjacent phase is understood to be one which is driven directly previously or subsequently. In the case of the magnetic coupling proposed, it is furthermore possible for the individual phases to be driven independently of one another.

The corresponding multiphase converter also makes it possible to avoid a complex three-dimensional construction and instead to have recourse to a substantially two-dimensional construction.

By virtue of the fact that coupling means are provided which magnetically couple at least one phase to at least three further phases, it is also possible to increase the fail-safety since a higher interlinking of the phases is obtained by means of the at least triple coupling, such that the failure of one phase cannot yet lead to unsafe operating states.

In one expedient development it is provided that such phases which have current profiles approximately in antiphase are coupled to one another. This results in a high level of compensation of the DC fields, such that the magnetic modulation can be reduced further. As a further consequence, the coupling means can become smaller or an air gap can be dispensed with.

In one expedient development it is provided that a first phase substantially has a planar, U-shaped course, while a second phase has a substantially rectangular, planar course. These phases formed in this way can be enclosed by coupling means, preferably commercially available ferrite cores. As a result, the desired coupling of at least three phases is achieved in a very simple manner with recourse to a matrix-shaped construction.

In one expedient development it is provided that the phases are embodied as leadframes. This type of production is distinguished by favorable manufacturing costs. In the case of a six-phase system, in this case three phases can be embodied in rectangular fashion and three phases in U-shaped fashion. The same geometrical shapes can substantially be used, thus making manufacture even more expedient.

In one expedient development it is provided that the phases are part of a multilayered printed circuit board. Thus, the phases to be coupled to one another can be introduced in a manner electrically insulated from one another on at least two planes. A printed circuit board preferably has corresponding cutouts into which the limbs of the respective coupling means are introduced for the purpose of magnetically coupling the respective phases. Expediently, the phases in the case of a printed circuit board can also be embodied in multilayered fashion with corresponding parallel connection.

In one expedient development it is provided that one phase is coupled to a further phase for at least partial compensation of the DC component of the current profile. In one particularly expedient development it is provided that one phase is magnetically coupled to at least one further phase driven in a manner phase-shifted substantially by approximately 180°. This results in a particularly high level of compensation of the DC fields, such that the magnetic modulation can be reduced further. As a further consequence, the coupling means can become smaller or an air gap can be dispensed with. By virtue of this type of coupling of the phases, the coupling means can be provided in a geometrically advantageous matrix arrangement. The latter is distinguished by simple construction, the use of simple coupling means such as planar ferrite cores, and a small spatial extent. Moreover, filters can be given smaller dimensions.

In one expedient development it is provided that the switching means to drive the phases sequentially, and in that one phase is magnetically coupled to at least one further phase driven directly previously and/or subsequently. In one particularly expedient development it is provided that one phase is magnetically coupled to at least one further phase having a directly preceding and/or succeeding switch-on or switch-off instant. In one expedient development it is provided that one phase is magnetically coupled to at least two further phases respectively driven directly previously and subsequently.

These instances of driving result in relatively simple current profiles, which can therefore also be controlled relatively simply.

In one expedient development it is provided that three coupling means are provided in order to magnetically couple one of the phases to three further phases. In one particularly expedient development it is provided that exactly six phases are provided, wherein the coupling means magnetically couple each of the six phases to three further phases of the six phases. This type of coupling firstly ensures that the individual phases can still be controlled independently of one another. Moreover, the fail-safety of the multiphase converter can be increased on account of the greater interlinking of the phases.

In one expedient development it is provided that the phases run spatially substantially on parallel planes. In one particularly expedient development it is provided that at least three phases run spatially in a first plane and that at least three further phases run spatially in a second plane, which is parallel to and spaced apart from the first plane. This makes possible a construction of the multiphase converter that is cost-effective and simple in terms of production engineering, since, in particular, two-dimensional phase shapes can be used. In one expedient development it is provided for this purpose that at least one phase is embodied in a U-shaped, rectangular and/or meandering fashion. By virtue of these geometries, all couplings of the preferably six phases can be performed with just two phase shapes, namely U-shaped and rectangular and/or meandering. By virtue of having recourse to only two different shapes in the case of preferably six phases, the proportion of shared components in the arrangement is increased, as a result of which the manufacturing costs are reduced further. In one expedient development it is provided that the phases are constructed as leadframes and/or as part of a printed circuit board. This type of manufacture is particularly cost-effective. In the the integration of at least one portion of the phases in a printed circuit board, further electronic components such as the switching means can be arranged there. In one expedient development it is provided that the printed circuit board comprises at least two, preferably three, cutouts for receiving the coupling means. This simplifies the positionally correct arrangement of the coupling means relative to the phases integrated at least partly in the printed circuit board.

In one expedient development it is provided that the phase embodied in a rectangular and/or meandering fashion has at least one chamfer in the region of a corner. In one expedient development it is provided that, in the case of at least one of the phases, a folding region is provided outside the region enclosed by the coupling means. What is achieved by the measures provided is that adjacent coupling means can move spatially closer together. This becomes apparent in a reduction of structural space.

In one expedient development it is provided that at least two phases to be coupled are at least partly enclosed by a coupling means, wherein the phases to be coupled can preferably be driven with different current directions. Preferably, the phases to be coupled run run at least partly approximately parallel in the region enclosed by the coupling means. In one particularly expedient development it is provided that the coupling means encloses at least two phases that are to be magnetically coupled in each case in a first region and in a second region. By virtue of this chosen type of coupling, it is possible to use standard parts such as, for example, planar ferrite cores as coupling means. These could have a rectangular or double-rectangular cross section. In one expedient development it is provided that the coupling means are arranged in a matrix-type fashion. Particularly in the case of a rectangular outer contour of the coupling means, in the case of the proposed coupling in the case of six phases the new coupling means required can be arranged in a matrix-type fashion (3×3) and thus in a space-saving and planar fashion. In one expedient development it is provided that the coupling means comprises at least two parts, wherein one of the parts has a U-, O-, I- or E-shaped cross section. By virtue of this construction, the phases to be coupled can be surrounded by the coupling means in a particularly simple manner. In one expedient development it is provided that a gap, preferably an air gap, is provided between two parts. The inductance can be influenced particularly simply in this way. In one expedient development it is provided that a plurality of coupling means consisting of at least two parts have at least one common part, preferably a metal plate. This could facilitate assembly since all the coupling means could be closed in only one step by the placement of the plate.

In one expedient development it is provided that at least two, in particular three, coupling means are provided in order to magnetically couple one of the phases to two further phases, wherein at least one of the two coupling means has a lower inductance than the other coupling means. Various aspects can be influenced and optimized by means of a targeted choice of the inductance of the coupling means. Firstly, the inductance influences the power loss and thus also the evolution of heat in the coupling means. A reduction of the inductance also reduces the power loss. Moreover, a lower inductance can serve as saturation protection. As a result, coupling means having a lower inductance become saturated only later at higher currents, such that in the case of a fault the multiphase converter can still be operated longer in a stable operating state. On the other hand, a high inductance reduces the current ripple. The loss distribution, saturation behavior and current ripple can thus be optimized with the choice of the suitable inductance.

In one expedient development it is provided that the coupling means which couples one phase to one phase driven in a manner phase-shifted substantially by approximately 180° has a lower inductance than at least one of the other coupling means. As a result, these coupling means, which are generally subjected to higher loading, can be reduced with regard to the losses, such that a reduced evolution of heat is also obtained.

In one expedient development it is provided that three coupling means are provided in order to magnetically couple one of the phases to three further phases, wherein at least one of the three coupling means has a lower inductance than the other two coupling means. Saturation protection is thus realized for one phase, said saturation protection having a positive effect on the system stability. Expediently, a coupling means having a lower inductance should be provided for each of the preferably six phases. In one expedient development it is provided that the coupling means is provided with an air gap. The inductance of the coupling means can thereby be influenced in a particularly simple manner. If an air gap is provided in the case of an otherwise identical design of the coupling means, the inductance is reduced relative to the version without an air gap. This can be effected particularly expediently by the middle one of the three limbs of the coupling means being shortened relative to the two outer limbs, such that an air gap forms there.

### BRIEF DESCRIPTION OF THE DRAWINGS

A number of exemplary embodiments are illustrated in the figures and are described in greater detail below.

In the figures:

FIG. 1 shows a circuit arrangement,

FIG. 2 shows a schematic illustration of the respective coupling of the phases,

FIG. 3 shows the spatial arrangement of the various phases and coupling means,

FIG. 4 shows a section through a coupling means with two coupled phases,

FIG. 5 shows two typical configurations of the phases in accordance with the exemplary embodiment according to FIG. 3,

FIG. 6 shows a further exemplary embodiment with seven phases,

FIG. 7 shows the driving and current profiles in the case of the exemplary embodiment in accordance with FIG. 1,

FIG. 8 shows the temporal current profiles of the first phase 11 and fourth phase 14 and underneath the difference between the two currents,

FIG. 9 shows one basic possibility of coupling three phases,

FIG. 10 shows an alternative exemplary embodiment with folded phases and at the bottom the associated plan view,

FIG. 11 shows a further alternative exemplary embodiment with chamfered meandering phases,

FIG. 12 shows an alternative exemplary embodiment of a coupling means with an air gap, and

FIG. 13 shows one possible realization of the exemplary embodiment according to FIG. 3 with a printed circuit board.

### DETAILED DESCRIPTION

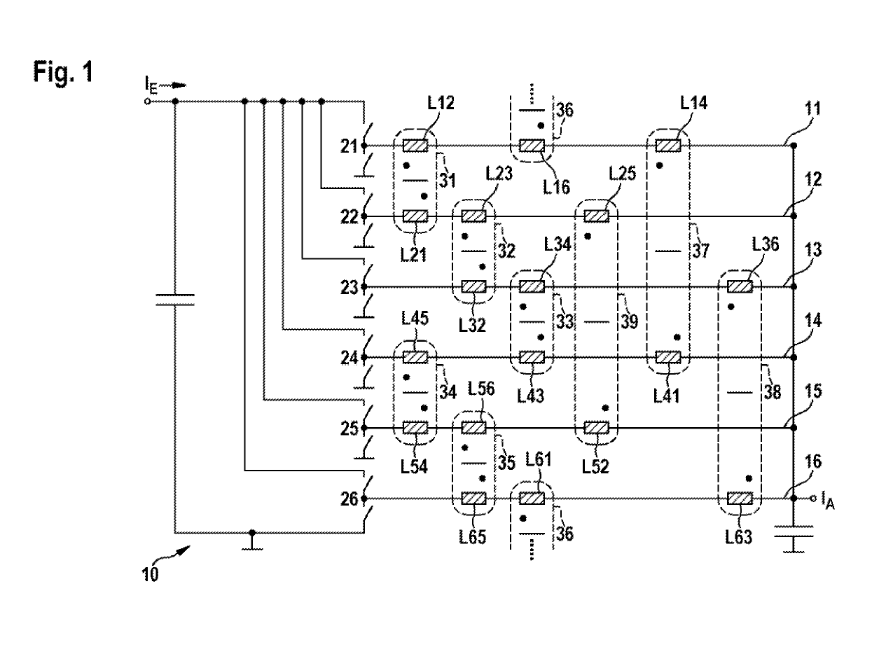

The construction of a multiphase converter 10 is illustrated in terms of circuitry in accordance with FIG. 1. The multiphase converter 10 described here by way of example consists of six phases 11 to 16. Each of the phases 11 to 16 can be driven individually via corresponding switching means 21 to 26, each consisting of a high-side switch and a low-side switch. On account of magnetic coupling to three further phases, each current of the phases 11 to 16 flows through three inductances Lxx brought about by the corresponding coupling means 31 to 39. A first coupling means 31 magnetically couples the first phase 11 to the second phase 12, thus resulting in an inductance L12 for the first phase 11 and an inductance L21 for the second phase 12. A sixth coupling means 36 magnetically couples the first phase 11 to the sixth phase 16, thus resulting in an inductance L16 for the first phase 11 and an inductance L61 for the sixth phase 16. A seventh coupling means 37 magnetically couples the first phase 11 to the fourth phase 14, thus resulting in an inductance L14 for the first phase 11 and an inductance L41 for the sixth phase 16. A second coupling means 32 magnetically couples the second phase 12 to the third phase 13, thus resulting in an inductance L23 for the second phase 12 and an inductance L32 for the third phase 13. A ninth coupling means 39 magnetically couples the second phase 12 to the fifth phase 15, thus resulting in an inductance L25 for the second phase 12 and an inductance L52 for the fifth phase 15. A third coupling means 33 magnetically couples the third phase 13 to the fourth phase 14, thus resulting in an inductance L34 for the third phase 13 and an inductance L43 for the fourth phase 14. An eighth coupling means 38 magnetically couples the third phase 13 to the sixth phase 16, thus resulting in an inductance L36 for the third phase 13 and an inductance L63 for the sixth phase 16. A fourth coupling means 34 magnetically couples the fourth phase 14 to the fifth phase 15, thus resulting in an inductance L45 for the fourth phase 14 and an inductance L54 for the fifth phase 15. A fifth coupling means 35 magnetically couples the fifth phase 15 to the sixth phase 16, thus resulting in an inductance L56 for the fifth phase 15 and an inductance L65 for the sixth phase 16.

An input current I_{E} is distributed among the six phases 11 to 16. At the input, a capacitor as filter means is connected to ground. The outputs of the phases 11 to 16 are combined at a common summation point and connected to ground by means of a capacitor (not designated more specifically) as filter means. The output current I_{A} is then present at the common output-side summation point. The inductances Lxx respectively coupled to one another are oriented with different winding senses with respect to one another, as indicated by the corresponding dots in FIG. 1.

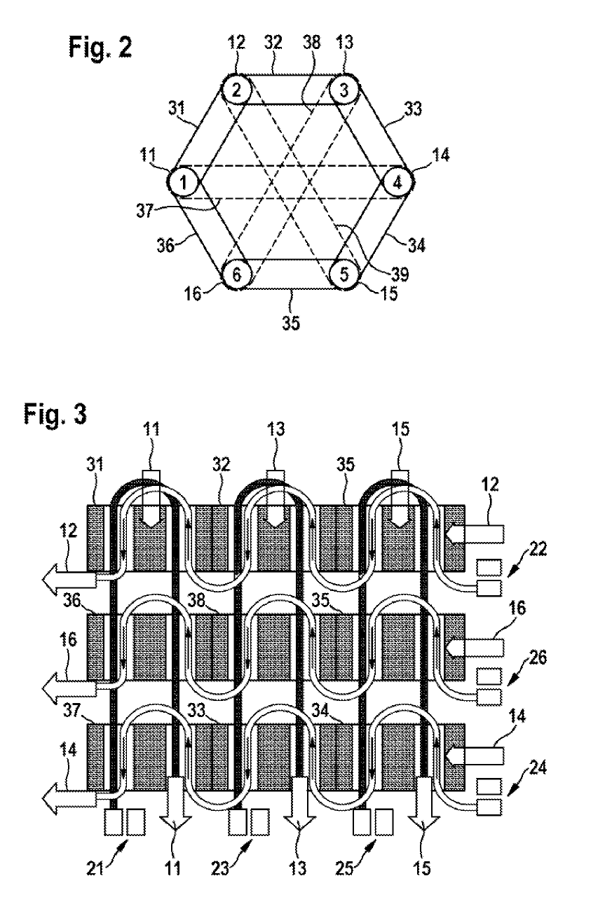

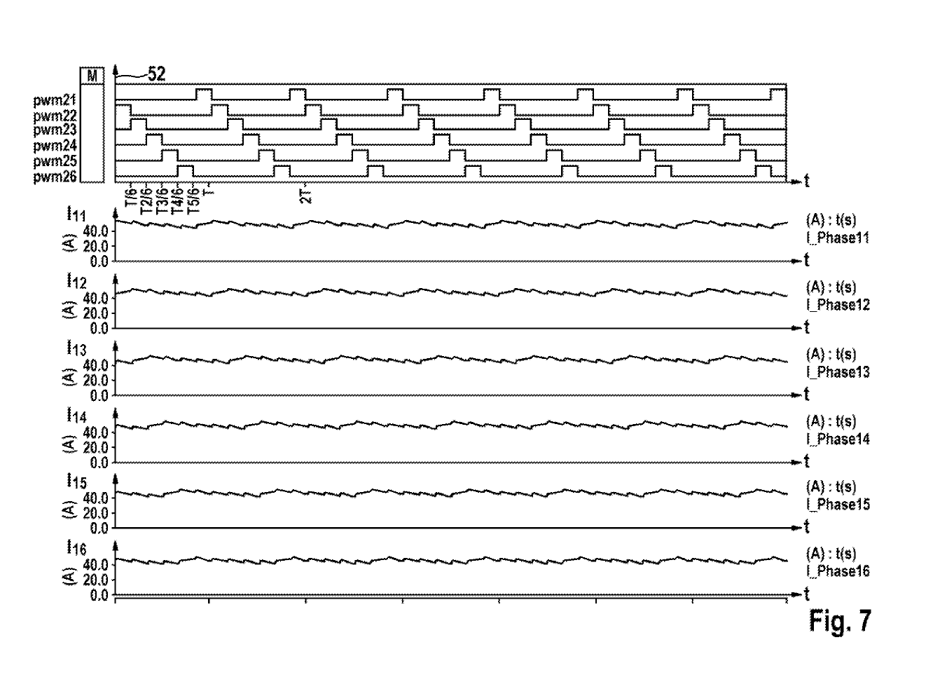

FIG. 2 systematically illustrates how the six phases 11 to 16 are coupled to one another by corresponding coupling means 31 to 39. As already described in conjunction with FIG. 1, not only are adjacent phases coupled to one another but also additionally the phase offset by 180 degrees. An adjacent phase is understood to be one which is driven temporally directly previously or subsequently, that is to say has temporally directly preceding or succeeding switch-on instants. In the exemplary embodiment here the designation of the phases 11 to 16 is chosen such that the phases 11 to 16 are driven successively in accordance with the numbering, that is to say in the order (indications correspond to the reference signs of the phases): 11-12-13-14-15-16-11, etc., in each case in a manner phase-shifted by 60 degrees or by T/6 (360 degrees/number of phases), wherein T represents the period duration of a drive cycle. This order is also shown in FIG. 2 and FIG. 7. That is to say that the start instants for the various phases 11 to 16 are phase-shifted by 60 degrees in each case or temporally shifted by T/6 in each case. In FIG. 7, although the respective phase is switched off again after the temporal duration T/6 (PWM ratio 1/6), depending on the desired voltage ratio the switch-off could be effected earlier or later, through to duration-on Te, depending on the desired PWM signal (between 0% (duration-off, Te=0) and 100% (duration-on, Te=T), relative to a period duration T).

FIG. 3 then schematically depicts the matrix-like spatial construction of the concept shown in FIG. 2. In this case, the coupling means 31 to 39 are preferably embodied as planar coil cores, for example ferrite cores, which each have two cavities. In said cavities of the coupling means 31 to 39, in each case two conductors or phase sections of two phases to be coupled are enclosed, which have different current directions in these sections, as indicated by the arrows.

Referring also to FIG. 5, it is possible to discern two geometrical shapes of phases 11 to 16 or busbars or conductors of the phases 11 to 16. The first phase 11, third phase 13 and fifth phase 15 are embodied in a U-shaped fashion. These three phases 11, 13, 15 preferably all run in the same plane. In a further plane parallel to and spaced apart therefrom—above in the exemplary embodiment in accordance with FIG. 3—there run the second, fourth and sixth phases 12, 14, 16. The second, fourth and sixth phases 12, 14, 16 are embodied in a rectangular or meandering fashion. In this case, they are arranged such that they are enclosed with the phase to be coupled in each case, U-shaped phase 11, 13, 15, in the respective coupling means 31 to 39 with a different current direction.

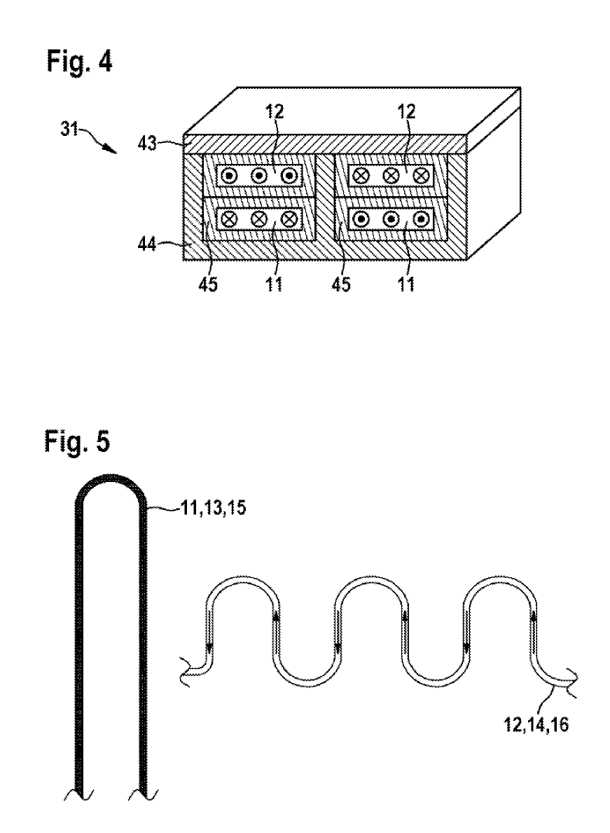

Referring to the sectional illustration in FIG. 4, the coupling illustrated in FIG. 3 is explained by way of example on the basis of the first phase 11 and the second phase 12. The first coupling means 31 consists of an E-shaped first part 44 and a plate-shaped second part 43, which form the coil cores. The limbs of the first part 44 having an E-shaped cross section are all of the same length, such that they can be closed by the plate-shaped (I-shaped cross section) second part 43 without an air gap. The preferably strip-shaped section of the first phase 11 is in each case introduced in the lower region of the coupling means 31. These sections of the first phase 11 shown lie in the same plane, that is to say are planar with respect to one another. The current direction corresponds to that current direction indicated by arrows in accordance with FIG. 3. The second phase 12, preferably likewise embodied in a strip-shaped fashion, then becomes situated in the respective overlying region of the first coupling means 31. On the other side of the first coupling means 31, in the further cavity thereof, first and second phases 11, 12 are led through with a respective opposite current direction relative to the current direction in the other cavity. In the case of the first coupling means 31, this is effected by virtue of the fact that both the first phase 11 and the second phase 12 are led back again at the upper end side of the first coupling means 11 in a 180 degrees bend through the other cavity. The two sections of the second phase 12, which are enclosed by the first coupling means 31, are also situated in the same plane, that is to say are embodied in a planar fashion. The plane of the first phase 11 and the plane of the second phase 12 are embodied such that they are parallel to and spaced apart from one another at least in the inner region of the first coupling means 31.

The first phase 11 and the second phase 12 are then magnetically coupled to one another by the first coupling means 31. The antiparallel current routing indicated achieves the effect of keeping the resulting magnetic field as low as possible, such that the size of the coupling means 31 can be minimized. Moreover, between the first phase 11 and the second phase 12 a respective insulation 45 is provided for electrically isolating the two phases 11, 12 from one another and in each case with respect to the coupling means 31.

The second phase 12 is coupled to the third phase 13 via the second coupling means 32 in the same way. Moreover, the second phase 12 is coupled to the fifth phase 15 by means of the ninth coupling means 39. The further corresponding couplings can be gathered from FIG. 3 and will not be described separately again.

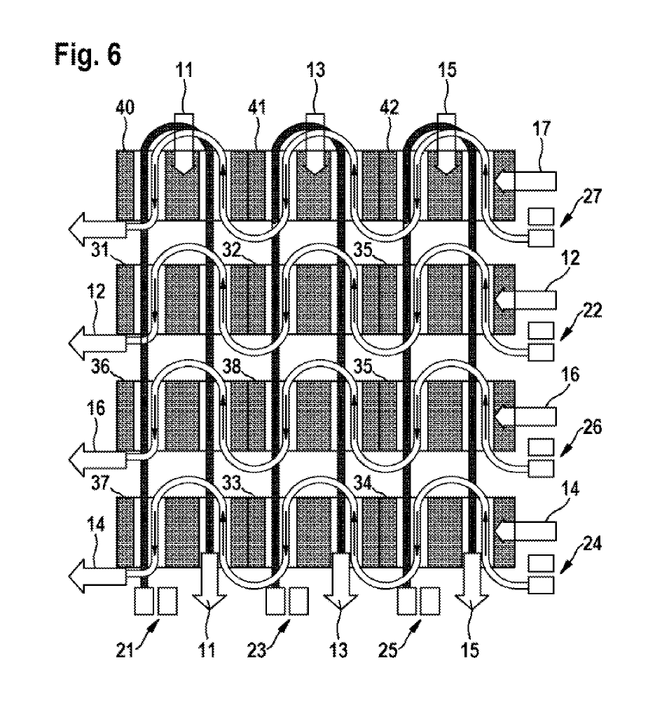

The exemplary embodiment in accordance with FIG. 6 differs from that according to FIG. 3 merely in that a further, seventh phase 17 is also provided. This seventh phase 17 is in each case magnetically coupled to the first phase 11 by the tenth coupling means 40, to the third phase 13 by the eleventh coupling means 41 and to the fifth phase 15 by the twelfth coupling means 42. This exemplary embodiment is intended to illustrate that other multiphase systems having a different phase number than n=6 can also be used, without dispensing with the basic concept of the at least triple coupling, whilst maintaining a suitable matrix-type, substantially two-dimensional arrangement.

The diagram in accordance with FIG. 7 shows the temporal profiles of the drive signals 52 for the respective switching means 21 to 26 of the corresponding phases 11 to 16 and the current profiles in the phases 11 to 16. The switching means 21 to 26 energize the associated phases 11 to 16 successively for in each case one sixth of a period duration T, for example by means of a PWM signal, and are subsequently freewheeling. The resultant current profiles of the individual phases 11 to 16 are shown by way of example underneath. The period duration T of the drive signals 52 is of the order of magnitude of 0.01 ms, for example. The start instants for the various phases 11 to 16 are phase-shifted by 60 degrees in each case or temporally offset by T/6. The start instant of the second phase 12 with the corresponding drive signal 52 of the second switching means 22 is at t=0 and is switched off again (depending on the desired PWM ratio) after 1/6 T. The start instant of the third phase 13 adjacent to the second phase 12 is at T/6, the start instant of the fourth phase 14 is at 2T/6, and so on. Although in FIG. 7 the respective phase is switched off again after T/6 (PWM ratio 1/6), depending on the desired voltage ratio the switch-off could be effected earlier or later, through to duration-on, depending on the desired PWM signal (between 0% (duration-off) and 100% (duration-on)). That is to say that at a specific instant a plurality of phases 11 to 16 could also be energized simultaneously if this is required by the desired voltage ratios. However, the start instants are temporally offset.

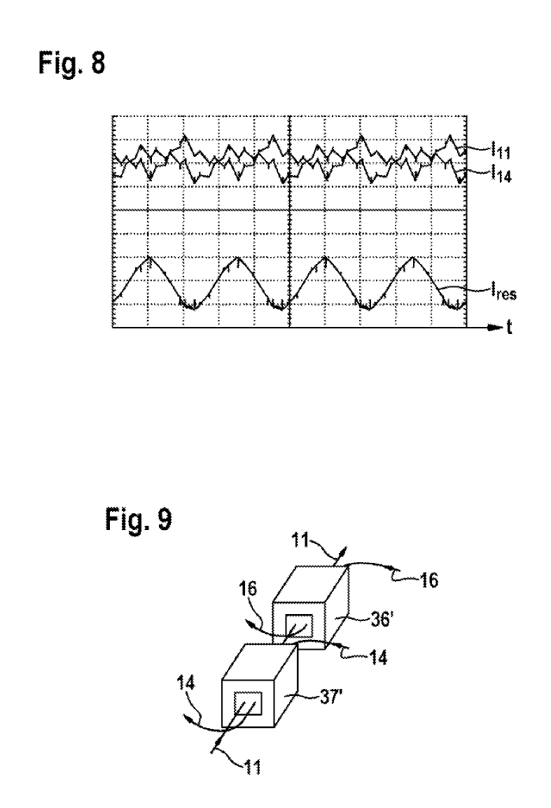

FIG. 8 shows the temporal current profiles of the first phase 11 and of the fourth phase 14 and underneath the difference between the two currents I res. In this case, it is evident that, relative to the first phase 11, the current profile of the fourth phase 14 is distinguished by the DC components largely running in opposite directions. The DC fields cancel one another out for the most part, as can be gathered from the lower curve I res in FIG. 8. Therefore, a coupling of the first phase 11—alongside a coupling to the adjacent phases 12, 16—to the fourth phase is particularly advantageous.

A further basic possibility for coupling three phases 11, 14, 16 is shown in FIG. 9. In this case, the first phase 11 and the sixth phase 16 energized in the opposite direction are enclosed by a sixth coupling means 36′ enclosing these two conductor sections. The first phase 11 and the fourth phase 14 energized in the opposite direction are enclosed by a seventh coupling means 37′. The coupling means 36′, 37′ have an O-shaped, or respectively rectangular cross section.

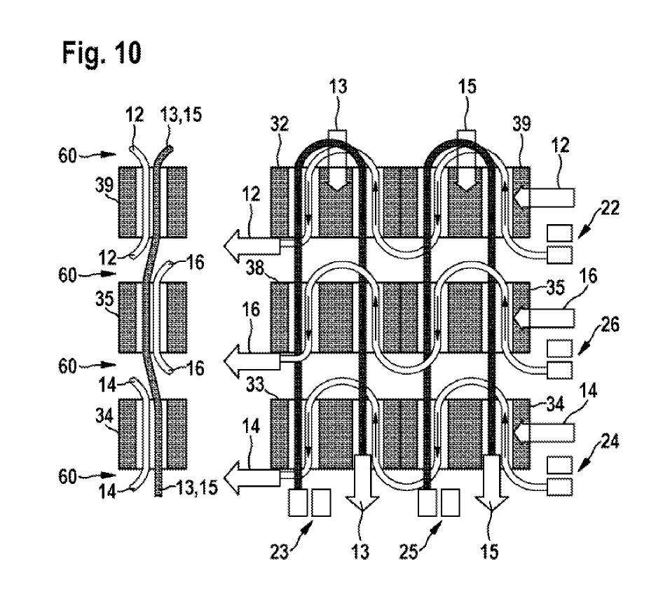

The exemplary embodiment according to FIG. 10 differs relative to that according to FIG. 3 in that the ends of the busbars of the phases 11 to 16 are folded in folding regions 60, indicated by arrows, as soon as they are led out from the interior of the coupling means 31 to 39. As a result, the coupling means, in FIG. 10 in each case those bearing the reference signs 39, 35; 35, 34; 32, 38; 38, 33, can move closer together. In this case, the meandering busbars of the respective phases 11 to 16 can also be bent up at the sides. As a result, the meanders can also be pushed into one another, as illustrated in the left-hand lateral schematic diagram in plan view. The U-shaped leadframes of the third and fifth phases 13, 15 would then have to run into different planes, however, for example by means of corresponding bending.

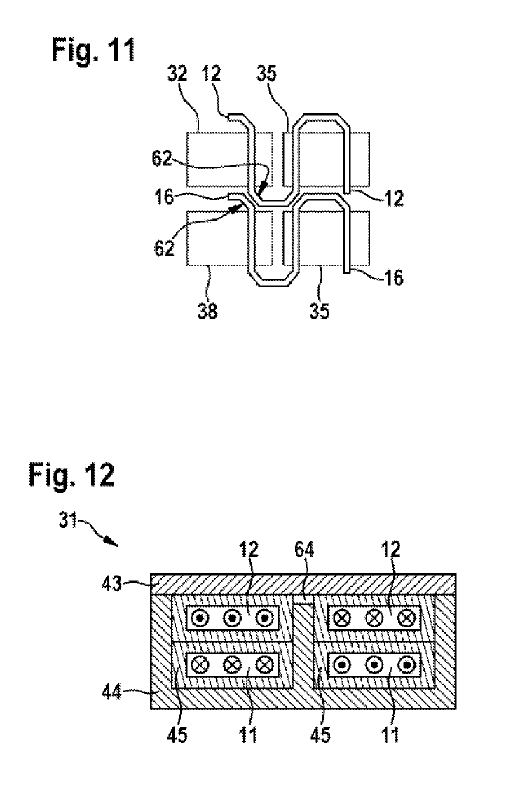

In the exemplary embodiment in accordance with FIG. 11, the phases 12, 14, 16 running in a meandering fashion are provided with chamfer regions 62 at the corners, such that preferably straight sections arise, in order to lead adjacent phases 12, 16 parallel to one another at a small distance in said chamfer regions 62. As a result, the coupling means 32, 38 and 39, 35 can likewise be pushed closer together.

The exemplary embodiment according to FIG. 12 differs from that according to FIG. 4 in that the middle limb of the E-shaped first part 44 has an air gap 64 in the direction of the second part 43.

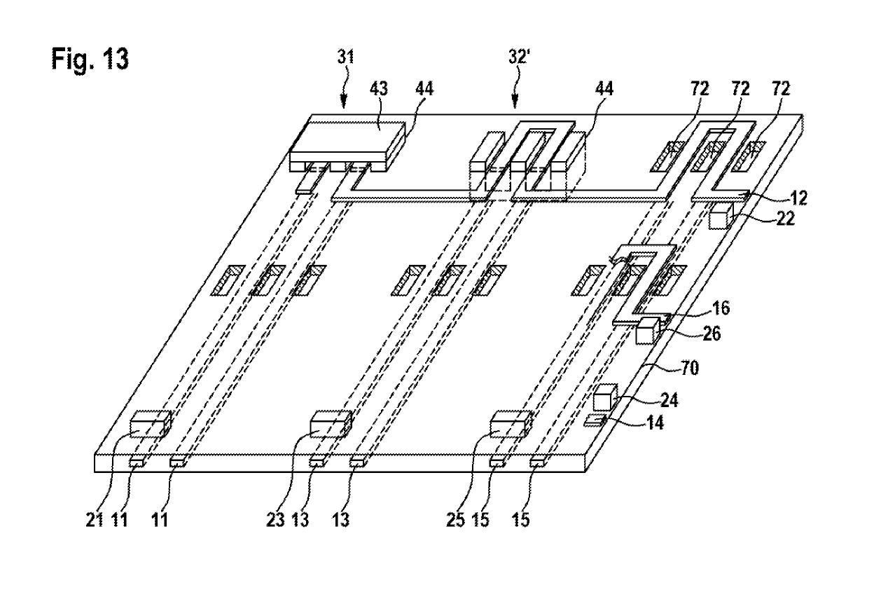

The exemplary embodiment according to FIG. 13 discloses one possible realization of the exemplary embodiment according to FIG. 3. First, third and fifth phases 11, 13, 15 are integrated in a printed circuit board 70, said phases running in a U-shaped fashion substantially in accordance with FIG. 5. The meandering phases 12, 14, 16 are arranged on the surface of the printed circuit board 70. The printed circuit board 70 has a multiplicity of rectangular cutouts 72. Three cutouts 72 are respectively coordinated with the geometry of the three limbs of the coupling means 31 to 42. For the second coupling means 32′, the three limbs of the first part 44 having an E-shaped cross section have already been inserted from below through the three cutouts 72 and project upward beyond the plane of the printed circuit board. The meander of the second phase 12 is fed around the middle limb for the purpose of magnetic coupling to the U-shaped third phase 13 situated in the printed circuit board 70. The magnetic circuit of the coupling means 31 is closed by placement of the second part 43. This is shown by way of example for the first coupling means 31, in the case of which the plate-shaped second part 43 has already been placed onto the three limbs of the first part 44.

The exemplary embodiments described operate in the manner explained in greater detail below. Multiphase converters 10 or DC/DC converters having high powers without special insulation requirements can preferably be realized in multiphase arrangements. The high input current I_{E}, for example with a magnitude of 300 A, is thereby distributed among the various six phases 11 to 16 with a magnitude of 50 A in each case. As a result of the subsequent superposition of the individual currents to form an output current I_{A}, it is possible to obtain a smaller AC current component. The corresponding input and output filters in accordance with FIG. 1, depicted as capacitors by way of example, can then turn out to be correspondingly small. The phases 11 to 16 are driven sequentially, that is to say successively, such that the switch-on instants are phase-shifted in each case by 60 degrees (or temporally by T/6) (in the case of the six-phase system described), as has already been shown in greater detail in FIG. 7. Depending on the desired voltage ratios, the respective phases 11 to 16 are energized with different durations. The corresponding high-side switch of the switching means 21 to 26 is closed for this purpose. The phase 11 to 16 is not energized if the corresponding low-side switch of the switching means 21 to 26 is closed. Alternatively, such phases 11 to 16 having directly preceding or succeeding switching-off instants could also be regarded as adjacent. The corresponding switch-on points would then be chosen variably depending on the desired PWM signal.

A respective phase 11 is then magnetically coupled together with at least three further phases 12, 14, 16, to be precise in such a way that the DC components of the individual phases are in each case compensated for by other phases to the greatest possible extent. This reduces the resulting magnetic field, such that the coupling means 31 to 39 or the magnetic circuit need be designed only substantially with regard to the magnetic field generated by the AC component. As a result, the coupling means 31 to 39 such as coil cores, for example, can be given correspondingly small dimensions, which leads to considerable savings in respect of coupling material, mass and costs. In particular the structural space can be greatly reduced as a result.

Alongside the two phases that are adjacent with regard to the driving (switch-on and/or switch-off instants), the third phase to be coupled is then preferably chosen in such a way that a disturbing mutual influencing of the phases is minimized. The choice is made such that an optimum compensation of the DC current component is obtained. In this case, it has been found that alongside the adjacent phases (+/−60 degrees phase shift of the switch-on instants in the case of six phases; for the first phase 11, the adjacent phases would therefore be the second phase 12 and the sixth phase 16) the phase having a phase offset of 180 degrees (for the first phase 11, this would be the fourth phase 14) is also particularly suitable since a very high extinction of the DC component arises there. FIG. 8 shows the temporal current profiles of the first phase 11 and fourth phase 14 and underneath the difference I res between the two currents. In this case, it is evident that, relative to the first phase 11, the current profile of the fourth phase 14 is distinguished by the DC component largely running in an opposite direction. Therefore, a corresponding further magnetic coupling of the first phase 11 to the fourth phase 14 is suitable. The two currents through the coupled phases 11, 14 flow oppositely in the seventh coupling means 37. In this case, the resulting current I res for the magnetization of the coupling means 37 is initiated only by the difference between the currents I res. The DC fields cancel one another out for the most part. The reduced DC component becomes apparent in a positive way for the geometry of the coupling means 31 to 39, which can now manage with a smaller volume. In the case of six phases 11 to 16, the coupling shown in FIGS. 1 to 3 has proved to be particularly suitable.

Magnetic Coupling

In principle, two phases can be magnetically coupled by the two phases being led with antiparallel current routing through a rectangular or ring-shaped coupling means 31 to 41. What is essential is that the coupling means 31 to 41 is able to form a magnetic circuit. This is possible in the case of a substantially closed structure, which can also comprise an air gap. Furthermore, the coupling means 31 to 41 consists of a magnetic-field-permeable material having suitable permeability.

One basic possibility for coupling three phases 11, 14, 16 is shown in FIG. 9. In this case, the first phase 11 and the sixth phase 16 energized in the opposite direction are enclosed by a sixth coupling means 36′ surrounding these two conductor sections. The first phase 11 and the fourth phase 14 energized in the opposite direction are enclosed by a seventh coupling means 37′. In the case of this coupling possibility, respectively half a turn of two phases 11, 16; 11, 14 are coupled to one another. The coupling means 36′, 37′ can be correspondingly composed for example of one part having a U- and I-shaped cross section or of two parts having a U-shaped cross section. As is shown in conjunction with FIGS. 3 and 4, however, an arrangement that is particularly advantageous geometrically is possible when using coupling means having E- and I- or E- and E-shaped cross sections with a whole turn in each case.

The coupling concept underlying FIG. 3 can be explained by way of example with reference to FIG. 4. What is essential is that the phases to be coupled—they are the first phase 11 and second phase 12 in accordance with FIG. 4—are driven with a current flow in opposite directions. The respectively corresponding magnetic fields substantially cancel one another out with regard to their DC component, such that predominantly only the AC component contributes to magnetic field generation. Consequently, the corresponding coupling means 31 to 41 can become smaller or an air gap can be dispensed with.

One possible concept for realizing the exemplary embodiment in accordance with FIG. 3 could consist of a printed circuit board 70 into which the nine coupling means 31 to 39, here preferably planar cores, are embedded, as shown in FIG. 13. All the switching means 21 to 26, in each case consisting of high-side or low-side MOSFETs as possible exemplary embodiments, can be integrated on said printed circuit board 70. The windings for the first, third and fifth phases 11, 13, 15 can also be integrated into said printed circuit board 70. The other windings of the second, fourth and sixth phases 12, 14, 16 could be realized by means of a more cost-effective copper leadframe. Alternatively, the further windings of the second, fourth and sixth phases 12, 14, 16 could also be integrated in the printed circuit board 70.

Realizations in which all windings are embodied in the form of copper rails or printed circuit boards would likewise be possible. A further advantage of the construction in accordance with FIG. 3 consists in the short paths of the phases 11 to 16 through all coupling means 31 to 39, and the simple construction without crossovers.

Construction of Coupling Means

The coupling means 31 to 41 are means for inductive coupling such as, for example, an iron or ferrite core of a transformer, on which the phases 11 to 16 to be coupled generate a magnetic field. The coupling means 31 to 42 closes the magnetic circuit of the two coupled phases 11 to 16.

The choice of the material of the coupling means 31 to 38 and of the permeability does not play such a major part for the coupling. If no air gap is used, the permeability of the magnetic circuit rises, as a result of which the inductance of the coil increases. As a result, the current rise becomes flatter and the current waveforms approximate more to the ideal DC current. The closer the waveforms come to a DC current, the smaller the resulting current difference between the two phases which are led (oppositely) through a core as coupling means 31 to 42. The outlay for filters is thereby reduced. On the other hand, a system without an air gap reacts very sensitively to different currents between the phases 11 to 16. Although the system tends toward attaining saturation in the case of smaller current faults, it is nevertheless still very stable as a result of the multiple coupling.

In principle, it is possible to choose air gaps with different dimensions in order to distribute the losses uniformly among the coupling means 31 to 42. Coupling means 31 to 42 having a lower inductance L also have, in principle, a lower power loss.

In order to obtain a good compromise between high permeability (no air gap→low current ripple) and high robustness (with air gap→high current ripple), different air gaps can be provided. In this way, the power losses of the coupling means 31 to 42 can also be influenced such that desired criteria (for example uniform distribution of the power loss) are fulfilled. In the case of the exemplary embodiment in accordance with FIG. 3, the coupling means in one of the diagonals (either coupling means 31, 38, 34 or 37, 38, 39) are to be provided with an air gap. As a result, with only three coupling means 31, 38, 34 or 37, 38, 39 with an air gap (which leads to a higher current ripple) on all the phases 11 to 16, this gives rise to a high protection against saturation and, associated therewith, a protection against an uncontrolled current rise. In the case of a great asymmetry between the phases 11 to 16 or else upon the failure of a plurality of phases 11 to 16, only individual coupling means 31 to 42 would attain saturation, but for a given current not all the coupling means 31 to 42 of one phase.

A further variant would be to form the coupling means 31 to 42 within the construction with different air gaps. The coupling means (in the exemplary embodiment according to FIGS. 1-3, they are the coupling means bearing the reference signs 37, 38, 39) which are loaded with a greater increased magnetization on account of the 180 degrees phase-offset driving (such as arises in the case of the exemplary embodiment according to FIGS. 1-3 by the coupling of the first phase 11 to the fourth phase 14 by the seventh coupling means 37; coupling of the second phase 12 to the fifth phase 15 by the ninth coupling means 39; coupling of the third phase 13 to the sixth phase 16 by the eighth coupling means 38) could be reduced in terms of their loading for example by adaptation or provision of an air gap. This would reduce the total core losses.

Furthermore, it would be possible, in the case of the matrix concept, in each row/column, to provide one coupling means 31 to 42 with a larger air gap or gap. As a result, this coupling means 31 to 42 provided with an air gap would become saturated only at higher currents, thus resulting in further improved stability in the case of a fault. For reasons of stability, it would be advantageous to lead each phase 11 to 16 through at least one coupling means 31 to 42, which attains saturation later than the other coupling means 31 to 42 in this phase as a result of the provision of a lower inductance L, which could be achieved by the provision of an air gap.

An example of a coupling means 31 provided with an air gap 64 is shown in the exemplary embodiment according to FIG. 12. For this purpose, the middle limb of the E-shaped first part 44 is embodied in a manner shortened somewhat relative to the outer limbs, thus giving rise to an air gap 64 in the direction of the second part 43. Alternatively, provision could be made for embodying the limbs of the E-shaped first part 44 with an identical size, but providing an air gap, for example by means of a non-magnetic film, between the ends of the limbs and the second part 43. The person skilled in the art is familiar with measures making it possible to obtain the desired inductance L of the respective coupling means 31 to 42, for example by provision of suitable air gap(s) at the suitable locations.

Construction of the Phases

It is particularly advantageous in terms of production engineering to use just two geometrical shapes of the phases 11 to 16, as illustrated in the plan view in FIG. 5. In this case, one basic shape has a U-shaped course and lie in the same plane. The second basic shape is substantially rectangular or meandering, likewise lying in the same plane. The sections shown can be integrated as strip conductors in the form of leadframes or in corresponding conductor tracks in a circuit board. As described in conjunction with FIGS. 3 and 6, the U-shaped phases 11, 13, 15 are arranged with respect to one another such that they become situated on a first plane. Correspondingly, the rectangular or meandering phases 12, 14, 16, 17 are also arranged such that they become situated on a second plane. These two planes are arranged parallel to and spaced apart from one another such that the phase sections that are respectively to be coupled can be surrounded by the coupling means 31 to 42.

In principle, however, alternative configurations of the phase shapes would also be conceivable, without departing from the basic concept of the preferably planar construction.

In particular, certain adaptations are conceivable in order to further reduce the space requirement of the overall arrangement. Corresponding variants are depicted schematically in FIGS. 10 and 11. What is intended to be achieved by means of a corresponding configuration of the geometry of the phases 11 to 17 is that the coupling means 31 to 42 can be arranged closer to the respectively adjacent coupling means 31 to 42. This can be achieved, for example, in accordance with the exemplary embodiment according to FIG. 10 by virtue of the fact that the ends of the busbars of the phases 11 to 16 are folded in folding regions 60 indicated by arrows. As soon as the coupled phase regions (such regions which are surrounded by the coupling means 31 to 42) leave the coupling means 31 to 42, the direction changes relative to that within the coupling means 31 to 42. As a result, the coupling means, in FIG. 10 those bearing the reference signs 39, 35; 35, 34; 32, 38; 38, 33, can move closer together. This is achieved by the phase sections of the second phase 12 and of the fifth phase 15 being folded at the end side by a specific angle, for example 45°. The sections of the fifth phase 15 and of the sixth phase 16 prior to entry into the fifth coupling means 35 are likewise folded by 45°, thereby avoiding contact with the second phase 12. As a result, ninth coupling means 39 and fifth coupling means 35 can be arranged at a smaller distance from one another than if the phase sections are led out without folding. In this case, the meandering busbars of the respective phases 11 to 16 can also be bent up at the sides. As a result, the meanders can also be pushed into one another, as illustrated in the left-hand lateral schematic diagram with plan view. The U-shaped leadframes of the third and fifth phases 13, 15 would then have to be shifted into different planes, however, for example by corresponding bending.

In the case of the exemplary embodiment in accordance with FIG. 11, the phases 12, 14, 16 running in a meandering fashion are provided with chamfer regions 62 at the curves or corners, such that preferably straight sections arise, in order to lead adjacent phases 12, 16 parallel to one another at a small distance in said chamfer regions 62. As a result, the coupling means 32, 38 or 39, 35 can likewise be pushed closer together. However, the adjacent phases (for example the phase sections 12, 16 in accordance with FIG. 11) can be arranged on the same plane.

Further possible embodiments extend to arrangements comprising more than six phases, such as, for example, seven phases with the exemplary arrangement in matrix form as shown in FIG. 6. Eight phases would also be possible, distributed among 4-by-4 coupling means. What is essential, however, is that the number of phases permits independent driving.

A further magnetic coupling of the individual cores of the coupling means 31 to 39 to form a large overall core can lead to further savings, for example by the provision of a single covering plate 43 for all lower parts of the nine coupling means 31 to 39.

The multiphase converter 10 described is suitable, in particular, for use in an on-board electrical system of a motor vehicle, in which, in particular, dynamic load requirements are of secondary importance. The construction described is suitable, in particular, for such comparatively sluggish systems.

1. A multiphase converter, comprising a plurality of phases (11 to 16), each of which can be driven by one of a plurality of switches (21 to 26), characterized in that a plurality of couplers (31, 36, 37) are provided, which magnetically couple at least one phase (11) to at least three further phases (12, 14, 16).

2. The device as claimed in claim 1, characterized in that one phase (11) is coupled to a further phase (14) for at least partial compensation of the DC component of the current profile.

3. The device as claimed in claim 1, characterized in that the plurality of switches (21 to 26) drive the phases (11 to 16) sequentially, and in that one phase (11) is magnetically coupled to at least one further phase (12, 16) driven directly previously and subsequently.

4. The device as claimed in claim 1, characterized in that one phase (11) is mechanically coupled to at least one further phase (12, 16) having a directly preceding and succeeding switch-on or switch-off instant.

5. The device as claimed in claim 1, characterized in that one phase (11) is magnetically coupled to at least one further phase (14) driven in a manner phase-shifted approximately 180°.

6. The device as claimed in claim 1, characterized in that exactly six phases (11 to 16) are provided, wherein the plurality of couplers (31 to 39) magnetically couple each of the six phases (11 to 16) to three further phases of the six phases (11 to 16).

7. The device as claimed in claim 1, characterized in that at least three phases (11, 13, 15) run spatially in a first plane and in that at least three further phases (12, 14, 16) run spatially in a second plane, which is parallel to and spaced apart from the first plane.

8. The device as claimed in claim 1, characterized in that at least one phase (11, 13, 15) is embodied in a U-shaped, rectangular and meandering fashion.

9. The device as claimed in claim 1, characterized in that the phases (11 to 16) are constructed as leadframes and as part of a printed circuit board (70).

10. The device as claimed in claim 1, characterized in that at least two phases (11, 12) to be coupled can be driven with different current directions at least in the region in which they are enclosed by the coupling means (31).

11. The device as claimed in claim 1, characterized in that the plurality of switches (21 to 26) drive the phases (11 to 16) sequentially, and in that one phase (11) is magnetically coupled to at least one further phase (12, 16) driven directly previously.

12. The device as claimed in claim 1, characterized in that the plurality of switches (21 to 26) drive the phases (11 to 16) sequentially, and in that one phase (11) is magnetically coupled to at least one further phase (12, 16) driven directly subsequently.

13. The device as claimed in claim 1, characterized in that one phase (11) is mechanically coupled to at least one further phase (12, 16) having a directly preceding switch-on or switch-off instant.

14. The device as claimed in claim 1, characterized in that one phase (11) is mechanically coupled to at least one further phase (12, 16) having a directly succeeding switch-on or switch-off instant.

15. The device as claimed in claim 1, characterized in that at least one phase (11, 13, 15) is embodied in a U-shaped, rectangular fashion.

16. The device as claimed in claim 1, characterized in that at least one phase (11, 13, 15) is embodied in a U-shaped, meandering fashion.

17. The device as claimed in claim 1, characterized in that the phases (11 to 16) are constructed as leadframes.

18. The device as claimed in claim 1, characterized in that the phases (11 to 16) are constructed as part of a printed circuit board (70).
